(19) United States
(12) Patent Application Publication
(10) Pub. No.: US 2008/0115832 A1
(43) Pub. Date: May 22, 2008

(54) POLYMER ELECTROLYTE USING TITANIA NANOTUBES AND DYE-SENSITIZED SOLAR CELL USING THE POLYMER ELECTROLYTE

(76) Inventors: O-Bong YANG, Jeonju City (KR); Hyun-Cheol Lee, Jeonju City (KR); Ji-Min Chun, Jeonju City (KR); M. Shaheer Akhtar, Jeonju City (KR); Chae-Woung Cho, Iksan City (KR)

Correspondence Address: MORGAN & FINNEGAN, L.L.P., 3 WORLD FINANCIAL CENTER, NEW YORK, NY, 10281-2101, US

(21) Appl. No.: 11/856,244

(22) Filed: Sep. 17, 2007

(30) Foreign Application Priority Data
Nov. 22, 2006 (KR) 10-2006-0115977
Jun. 26, 2007 (KR) 10-2007-0062814

(51) Int. Cl. H01L 31/0224

(52) U.S. Cl. 136/263

(57) ABSTRACT

A polymer electrolyte using titania nanotubes (TiNTs) is disclosed. The polymer electrolyte is prepared by crosslinking titania nanotubes with a conductive polymeric material and adding an iodine-based solution thereto. Further disclosed is a dye-sensitized solar cell using the polymer electrolyte.

### BACKGROUND OF THE INVENTION

1. Field of the Invention

The present invention relates to a polymer electrolyte using titania nanotubes (TiNTs) and a dye-sensitized solar cell using the polymer electrolyte. More specifically, the present invention relates to a polymer electrolyte prepared by crosslinking titania nanotubes with a conductive polymeric material and adding an iodine-based solution (a solution of LiI and/or I₂) thereto, and a dye-sensitized solar cell using the polymer electrolyte.

2. Description of the Related Art

In general, dye-sensitized solar cells are kinds of solar cells that use the ability of dyes to absorb sunlight energy to convert solar energy into electric energy. Each dye-sensitized solar cell is comprised of a cathode, a dye, an electrolyte, a counter electrode, a transparent conductive electrode, etc., formed on a glass substrate.

The cathode is composed of an n-type oxide semiconductor (e.g., TiO₂ or ZnO) having a wide bandgap. Upon illumination of solar energy, dye molecular absorb the light and move to excited state. It injects electron into conduction band of the semiconductor and leave holes behind

At this time, redox electrolyte supply electrons to regenerate the dye molecule, and the counter electrode supplies electrons to redox couple for regeneration of the ions. The counter electrode is provided with a thin layer (e.g., a thin platinum layer) having high catalytic activity to promote redox reaction of the ions contained in the electrolyte.

Conventional dye-sensitized solar cells using a liquid electrolyte exhibit a high energy conversion efficiency (˜11% at 1sun, AM1.5) and a low production cost (one-fifth that of silicon solar cells), and are thus proposed as potential candidates for renewable energy. However, the disadvantages of such conventional dye-sensitized solar cells are solvent volatility and liquid leakage.

Under these circumstances, efforts are currently being made to develop polymer gel electrolytes that are not readily volatilized and are highly efficient to enhance the stability of solar cells.

The efficiency of conventional polymer gel electrolytes using nanoparticles and a polymer is not high. Thus, there is a need for research to improve the efficiency of highly stable polymer gel electrolyte.

### SUMMARY OF THE INVENTION

The present invention has been made in view of the problems of the prior art, and it is one object of the present invention to provide a highly efficient polymer gel electrolyte that has high ionic conductivity and excellent electrical properties.

It is another object of the present invention to provide a dye-sensitized solar cell using the polymer gel electrolyte.

In accordance with one aspect of the present invention for achieving the above objects, there is provided a polymer electrolyte that is prepared by mixing an iodine-based solution and titania nanotubes in a solution of a conductive polymeric material.

The solution of a conductive polymeric material is prepared by dissolving a polymeric material based on polyethylene glycol (PEG) or polyethylene oxide (PEO) in a solvent selected from acetonitrile, ethanol, ethylene carbonate (EC), γ-butyrolactam, propylene carbonate (PC), dimethyl carbonate (DMC) and mixtures thereof.

The iodine-based solution is a solution of lithium iodide (LiI) or iodine (I₂).

The iodine-based solution is prepared by mixing iodine (I₂) with an iodide selected from lithium iodide (LiI), sodium iodide (NaI) and potassium iodide (KI).

The titania nanotubes (TiNTs) have a concentration of 1% to 30%.

The polymer electrolyte of the present invention is prepared by mixing the solution of the conductive polymeric material, the iodine-based solution and the titania nanotubes in a stirring vessel for at least one day.

In accordance with another aspect of the present invention, there is provided a dye-sensitized solar cell that is filled with the polymer electrolyte.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a and 1b are cross-sectional views schematically showing a dye-sensitized solar cell comprising a polymer electrolyte of the present invention;

FIG. 2 is a diagram illustrating the migration of electrons within a polymer electrolyte of the present invention;

FIG. 3 shows states of dye-sensitized solar cells filled with polymer electrolytes according to preferred embodiments of the present invention; and

FIG. 4 shows current-voltage curves of dye-sensitized solar cells according to preferred embodiments of the present invention.

### DETAILED DESCRIPTION OF THE PREFERRED EMBODIMENTS

Specific constitution and effects of the present invention will now be described in more detail with reference to the accompanying drawings illustrating preferred embodiments.

The present invention provides a polymer electrolyte that is prepared by mixing an iodine-based solution and titania nanotubes in a solution of a conductive polymeric material in a stirring vessel. The stirring is preferably carried out for at least one day.

The solution of a conductive polymeric material is prepared by dissolving a conductive polymeric material in a solvent selected from acetonitrile, ethanol, ethylene carbonate (EC), γ-butyrolactam, propylene carbonate (PC), dimethyl carbonate (DMC) and mixtures thereof. The polymeric material may be polyethylene glycol (PEG) or polyethylene oxide (PEO).

The iodine-based solution may be a solution of lithium iodide (LiI) or iodine (I₂).

The iodine-based solution may be prepared by mixing iodine (I₂) with an iodide selected from lithium iodide (LiI), sodium iodide (NaI) and potassium iodide (KI). The iodine-based solution may be mixed with the solution of the conductive polymeric material in a predetermined ratio.

The mixing ratio between the iodine (I₂) and the iodide, which is selected from lithium iodide (LiI), sodium iodide (NaI) and potassium iodide, is not particularly limited. It is preferred that the amount of the iodide be greater than that of the iodine (I₂).

The concentration of the titania nanotubes mixed with the solution of the conductive polymeric material is not particularly limited. When the concentration of the titania nanotubes is excessively high, it is difficult for the polymer electrolyte to penetrate into voids of a porous layer, resulting in a deterioration in electrical properties. The concentration of the titania nanotubes is preferably limited to 1% to 30%. Accordingly, it is preferred to use the titania nanotubes (TiNTs) at a concentration of to 1% to 30%.

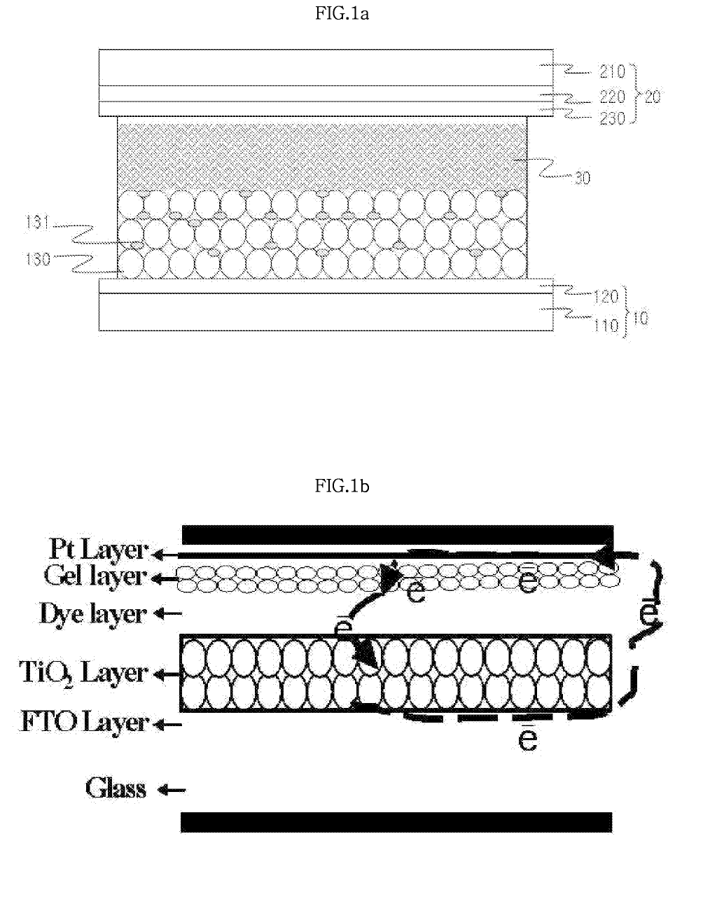

FIGS. 1a and 1b are cross-sectional views schematically showing a dye-sensitized solar cell comprising the polymer electrolyte of the present invention.

Referring to FIG. 1, the dye-sensitized solar cell of the present invention comprises a first lower electrode 10, a second upper electrode 20, a porous electrode 130 disposed on the first electrode and including a dye 131 adsorbed thereon, and a polymer electrolyte 30 filled between the second electrode and the porous electrode.

The first electrode 10 may include a substrate 110 and a transparent conductive electrode 120 formed on the inner surface of the substrate 110.

The second electrode 20 may include a substrate 210 and a transparent conductive electrode 220 formed on the inner surface of the substrate 210. The second electrode 20 may further include a thin catalyst electrode 230 formed under the transparent electrode 220.

The substrates 110 and 210 may be made of glass or a plastic material selected from polycarbonate (PC), polyimide (PI), polyethersulfone (PES), polyacrylate (PAR), polyethylene naphthalate (PEN), polyethylene terephthalate (PET) and triacetyl cellulose (TAC). The transparent conductive electrodes 120 and 220 may be made of indium tin oxide (ITO), fluorine-doped tin oxide (FTO), SnO₂ or ZnO.

The porous electrode 130 is a cathode that includes porous electrode particles having high specific surface area and a dye 131 adsorbed on the porous electrode particles. The dye may be composed of a monomolecular layer of ruthenium (Ru)-based material. The porous electrode 130 may be made of titanium dioxide (TiO₂).

Platinum is mainly used as a material for the thin catalyst electrode 230. Any conductive material may be used to produce the thin catalyst electrode 230. Examples of such conductive materials include ruthenium (Ru) and palladium (Pd).

The electrolyte layer 30 is formed by filling the polymer electrolyte of the present invention between the second electrode 20 and the porous electrode 130.

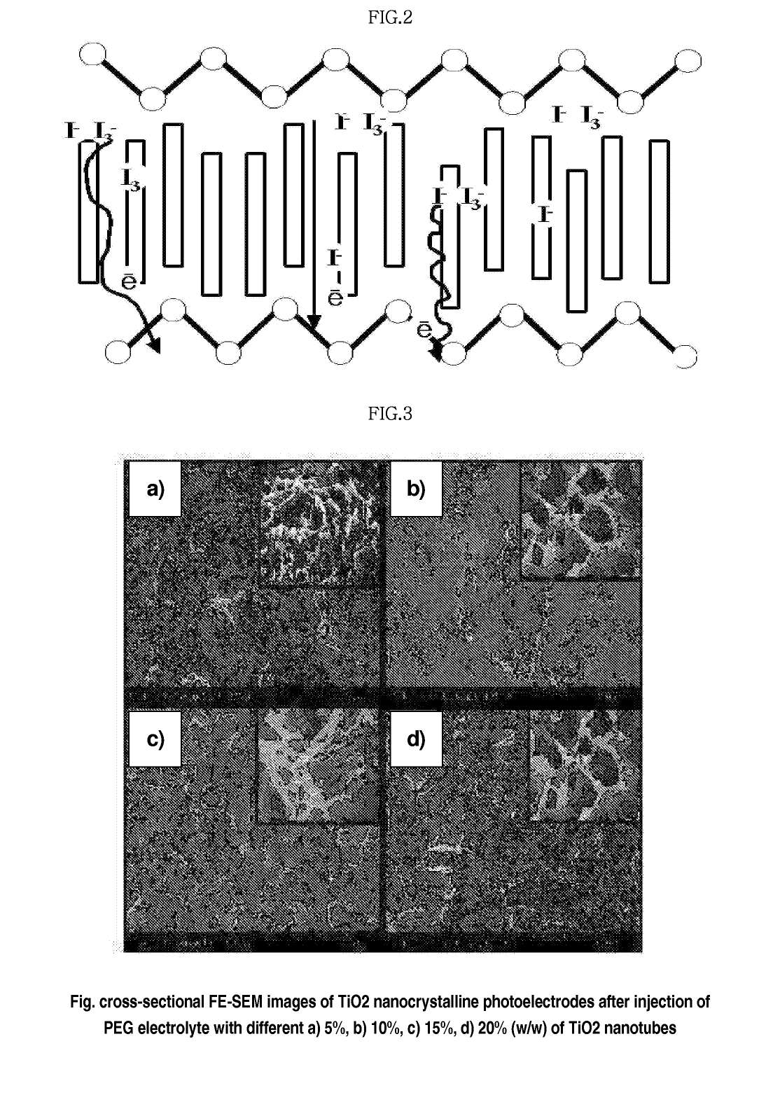

FIG. 2 is a diagram illustrating the migration of electrons within the polymer electrolyte of the present invention.

Referring to FIG. 2, the polymer electrolyte of the present invention is a mixture of titania nanotubes, an iodine-based solution (a solution of LiI and/or I₂) and a conductive polymeric material (e.g., PEG). The titania nanotubes act as fillers in the electrolyte and serve to improve the solubility of the lithium iodide (LiI).

The lithium (Li) ions bind to the bonding structure of the equally charged titanium of the titania nanotubes. As a result, a good crosslinking between the lithium ions and the titania nanotubes is obtained and provides good passages for the migration of the electrons.

To analyze the effects of the polymer electrolyte according to the present invention, LiI and I₂ (10:1) were mixed with different amounts of titania nanotubes in a 10% PEG solution to prepare polymer electrolytes. The titania nanotubes were used in amounts of 5%, 10%, 15% and 20% by weight. The electrolytes were filled to fabricate dye-sensitized solar cells.

FIG. 3 shows states of the dye-sensitized solar cells filled with the respective polymer electrolytes.

Although the polymer electrolytes are not of liquid type, the photographs of FIG. 3 demonstrate that the voids of the porous electrodes of the dye-sensitized solar cells were filled with the respective polymer electrolytes.

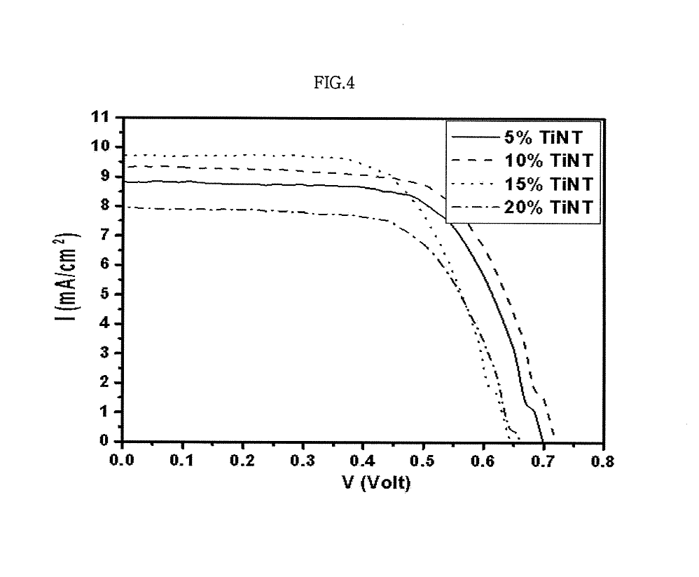

FIG. 4 shows current-voltage curves of the dye-sensitized solar cells.

The graph of FIG. 4 shows the electrical properties of the dye-sensitized solar cells. As can be seen from the graph, the best current characteristics were obtained in the dye-sensitized solar cell containing 15% (w/w) of the titania nanotubes and the best voltage characteristics were obtained in the dye-sensitized solar cell containing 10% (w/w) of the titania nanotubes.

TABLE 1

| w/w % of TiNTs | Isc | | | |
|---|---|---|---|---|
| in PEG electrolyte | (mA/cm²) | Voc (volt) | FF (%) | η (%) |
| Only PEG | 8.20 | 0.624 | 57.7 | 2.95 |
| 5% | 8.8 | 0.697 | 65.4 | 3.99 |
| 10% | 9.36 | 0.725 | 65.3 | 4.43 |
| 15% | 10.02 | 0.650 | 64.5 | 4.11 |
| 20% | 7.94 | 0.662 | 64.8 | 3.40 |

Table 1 shows comparative data for the electrical properties of the dye-sensitized solar cells of FIG. 4.

The data of Table 1 reveal that the dye-sensitized solar cell containing 15% (w/w) of the titania nanotubes showed the best current characteristics (Isc) (10.02 mA/m²), and that the dye-sensitized solar cell containing 10% (w/w) of the titania nanotubes showed the best voltage characteristics (Voc) (−0.725 V) and had a filling factor (FF) of 65.3% and an efficiency (η) of 4.43%. The experimental results were obtained using the dye-sensitized solar cells containing a 10% PEG solution and a mixture of lithium iodide (LiI) and iodine (I₂) (10:1). It is to be understood that the electrical properties of the dye-sensitized solar cells depending on the concentration of the titania nanotubes may be varied by changing the nature and the content of the solution of the conductive polymeric material and the iodine-based solution, and therefore, the scope of the present invention is not limited to the foregoing embodiments.

As apparent from the above description, the polymer electrolyte and the dye-sensitized solar cell using the polymer electrolyte according to the present invention have the following advantageous effects.

Firstly, the dye-sensitized solar cell of the present invention overcomes the disadvantages (e.g., liquid leakage and solvent evaporation) of conventional dye-sensitized solar cells using a liquid electrolyte. As a result, the dye-sensitized solar cell of the present invention is highly stable and thus its efficiency is maintained even after long-term operation.

Secondly, the titania polymer electrolyte of the present invention has a high efficiency close to 5%. In contrast, dye-sensitized solar cells using a polymer electrolyte, which are currently being developed as replacements for conventional dye-sensitized solar cells using a liquid electrolyte, are highly stable but have a lower efficiency than the dye-sensitized solar cells using a liquid electrolyte.

Thirdly, the nanocomposite material, which is prepared by crosslinking the titania nanotubes with the polymer solution, finds many useful applications not only in dye-sensitized solar cells but also in other various fields (including electrical devices).

The present invention has been described herein with reference to the preferred embodiments. These embodiments do not serve to limit the scope of the present invention. Those skilled in the art will appreciate that various modifications and variations can be made without departing from the spirit and scope of the present invention.

What is claimed is:

1. A polymer electrolyte prepared by mixing an iodine-based solution and titania nanotubes in a solution of a conductive polymeric material.

2. The polymer electrolyte according to claim 1, wherein the solution of a conductive polymeric material is prepared by dissolving a polymeric material based on polyethylene glycol (PEG) or polyethylene oxide (PEO) in a solvent selected from acetonitrile, ethanol, ethylene carbonate (EC), γ-butyrolactam, propylene carbonate (PC), dimethyl carbonate (DMC) and mixtures thereof.

3. The polymer electrolyte according to claim 1, wherein the iodine-based solution is a solution of lithium iodide (LiI) or iodine (I₂).

4. The polymer electrolyte according to claim 1, wherein the iodine-based solution is prepared by mixing iodine (I₂) with an iodide selected from lithium iodide (LiI), sodium iodide (NaI) and potassium iodide (KI).

5. The polymer electrolyte according to claim 1, wherein the titania nanotubes (TiNTs) have a concentration of 1% to 30%.

6. The polymer electrolyte according to claim 1, wherein the polymer electrolyte is prepared by mixing the solution of the conductive polymeric material, the iodine-based solution and the titania nanotubes in a stirring vessel for at least one day.

7. A dye-sensitized solar cell comprising a first electrode, a second electrode and an electrolyte filled between the first and second electrodes wherein the electrolyte is the polymer electrolyte according to any one of claims 1 to 6.
